(19) United States
(12) Patent Application Publication
(10) Pub. No.: US 2026/0048730 A1
(43) Pub. Date: Feb. 19, 2026

(54) APPARATUS AND METHOD FOR CONTROLLING BATTERY

(71) Applicants: Hyundai Motor Company, Seoul (KR); Kia Corporation, Seoul (KR)

(72) Inventor: Junghyun LEE, Hwaseong-Si (KR)

(21) Appl. No.: 19/297,445

(22) Filed: Aug. 12, 2025

(30) Foreign Application Priority Data
Aug. 19, 2024 (KR) 10-2024-0110545

(51) Int. Cl. B60W 20/13; B60W 50/00; G01R 31/374; G01R 31/3842; G01R 31/392; G07C 5/08; H01M 10/42; H01M 10/48

(52) U.S. Cl. CPC B60W 20/13; B60W 50/00; G01R 31/374; G01R 31/3842; G01R 31/392; G07C 5/0816; H01M 10/425; H01M 10/486; B60W 2050/0026; B60W 2510/246; B60W 2510/248; B60W 2710/244; H01M 2010/4271; H01M 2220/20

(57) ABSTRACT

An apparatus for a vehicle may comprise a processor and a memory storing at least one instruction that, when executed by the processor communicating with the memory, is configured to cause the apparatus to determine, via at least one sensor of the vehicle and based on a state of health (SOH) of a battery of the vehicle, a degradation state of the battery, output a signal indicating the determined degradation state of the battery, and control, based on the signal, at least one of charging or discharging of the battery by expanding at least one of a charge prohibition region or a discharge prohibition region of a state of charge (SOC) control strategy of the battery.

### CROSS-REFERENCE TO RELATED APPLICATION

This present application claims the benefit of priority to Korean Patent Application No. 10-2024-0110545, filed on Aug. 19, 2024, in the Korean Intellectual Property Office, the entire contents of which are incorporated herein by reference.

### FIELD

The present disclosure relates to an apparatus and method for controlling a battery, and more particularly, to an apparatus and method for controlling charging and discharging of a high-voltage battery used in eco-friendly vehicles.

### BACKGROUND

The matters described in this Background section are only for enhancement of understanding of the background of the disclosure, and should not be taken as acknowledgment that they correspond to prior art already known to those skilled in the art.

Eco-friendly vehicles, including hybrid electric vehicles (HEVs) and plug-in hybrid electric vehicles (PHEVs), may adopt state of charge (SOC) control strategies optimized for specific characteristics of each vehicle and battery to enhance vehicle system efficiency and ensure battery protection. For example, in high SOC regions, charging and regenerative braking are restricted to prevent overvoltage, while in low SOC regions, discharging is restricted to prevent undervoltage.

However, the SOC control strategies may be based on the assumption that the battery is in a new condition with minimal degradation, i.e., a state of health (SOH) of 100%. As a result, these strategies may fail to respond appropriately to situations in which the voltage rises sharply at high SOC or drops sharply at low SOC due to battery degradation.

Accordingly, durability and safety of the battery may deteriorate. In addition, during low-speed EV (Electric Vehicle) mode, the battery may shut off based on detection of overvoltage or undervoltage, resulting in a loss of vehicle driving power.

### SUMMARY

The following summary presents a simplified summary of certain features. The summary is not an extensive overview and is not intended to identify key or critical elements.

According to the present disclosure, an apparatus for a vehicle, the apparatus may comprise, a processor, and a memory storing at least one instruction that, when executed by the processor communicating with the memory, is configured to cause the apparatus to, determine, via at least one sensor of the vehicle and based on a state of health (SOH) of a battery of the vehicle, a degradation state of the battery, output a signal indicating the determined degradation state of the battery, and control, based on the signal, at least one of charging or discharging of the battery by expanding at least one of a charge prohibition region or a discharge prohibition region of a state of charge (SOC) control strategy of the battery.

The apparatus, wherein the at least one instruction, when executed by the processor communicating with the memory, is configured to cause the apparatus to, based on the determined degradation state of the battery, lower a lower limit of the charge prohibition region and raise an upper limit of the discharge prohibition region, and wherein the charge prohibition region and the discharge prohibition region are defined based on an SOC of the battery.

The apparatus, wherein the SOC control strategy defines, a first SOC region between the lower limit of the charge prohibition region and a first threshold SOC value of the battery, a second SOC region between the first threshold SOC value and a second threshold SOC value of the battery, and a third SOC region between the second threshold SOC value and the upper limit of the discharge prohibition region, and wherein the at least one instruction, when executed by the processor communicating with the memory, is configured to cause the apparatus to control charging and discharging of the battery such that the discharging is promoted in the first SOC region and suppressed in the third SOC region.

The apparatus, wherein the at least one instruction, when executed by the processor communicating with the memory, is configured to cause the apparatus to, retrieve at least one of a maximum charge power map or a maximum discharge power map of the battery, and reduce, based on the determined degradation state of the battery, at least one of a maximum power region of the maximum charge power map or a maximum power region of the maximum discharge power map.

The apparatus, wherein the at least one instruction, when executed by the processor communicating with the memory, is configured to cause the apparatus to, based on the SOH of the battery exceeding a predetermined threshold value, retain the maximum power region of the maximum charge power map and the maximum power region of the maximum discharge power map, and based on the SOH of the battery being equal to or less than the predetermined threshold value, reduce the maximum power region of the maximum charge power map and the maximum power region of the maximum discharge power map.

The apparatus, wherein the at least one instruction, when executed by the processor communicating with the memory, is configured to cause the apparatus to, detect, via a voltage sensor of the vehicle, a voltage of the battery, and based on the detected voltage of the battery exceeding a preset upper voltage threshold or falling below a preset lower voltage threshold, control at least one of charging or discharging of the battery by expanding at least one of the charge prohibition region or the discharge prohibition region.

The apparatus, wherein the at least one instruction, when executed by the processor communicating with the memory, is configured to cause the apparatus to, based on the detected voltage of the battery exceeding the preset upper voltage threshold and expanding the charge prohibition region, restrict charging of the battery.

The apparatus, wherein the at least one instruction, when executed by the processor communicating with the memory, is configured to cause the apparatus to, based on the detected voltage of the battery falling below the preset lower voltage threshold and expanding the discharge prohibition region, restrict discharging of the battery.

According to the present disclosure, a method performed by an apparatus, the method may comprise, determining, via at least one sensor and based on a state of health (SOH) of a battery, a degradation state of the battery, outputting a signal indicating the determined degradation state of the battery, modifying, based on the signal, a state of charge (SOC) control strategy by expanding at least one of a charge prohibition region or a discharge prohibition region of the SOC control strategy, and controlling, based on the modified SOC control strategy, at least one of charging or discharging of the battery.

The method, wherein the modifying may comprise, based on the determined degradation state of the battery, lowering a lower limit of the charge prohibition region, and raising an upper limit of the discharge prohibition region, and wherein the charge prohibition region and the discharge prohibition region are defined based on an SOC of the battery.

The method, wherein the SOC control strategy defines, a first SOC region between the lower limit of the charge prohibition region and a first threshold SOC value of the battery, a second SOC region between the first threshold SOC value and a second threshold SOC value of the battery, and a third SOC region between the second threshold SOC value and the upper limit of the discharge prohibition region, and wherein the controlling may comprise controlling charging and discharging of the battery such that the discharging is promoted in the first SOC region and suppressed in the third SOC region.

The method may further comprise, prior to the controlling, reducing, based on the determined degradation state of the battery, at least one of a maximum power region of a maximum charge power map of the battery or a maximum power region of a maximum discharge power map of the battery, wherein the controlling may comprise controlling, based on the maximum charge power map and the maximum discharge power map, at least one of charging or discharging of the battery.

The method, wherein the reducing may comprise, based on the SOH of the battery exceeding a predetermined threshold value, retaining the maximum power region of the maximum charge power map and the maximum power region of the maximum discharge power map, and based on the SOH of the battery being equal to or less than the predetermined threshold value, reducing the maximum power region of the maximum charge power map and the maximum power region of the maximum discharge power map.

The method may further comprise, prior to the modifying, detecting, via a voltage sensor, a voltage of the battery, wherein the modifying may comprise, based on the detected voltage of the battery exceeding a preset upper voltage threshold or falling below a preset lower voltage threshold, expanding at least one of the charge prohibition region or the discharge prohibition region of the SOC control.

The method, wherein the modifying may comprise, based on the detected voltage of the battery exceeding the preset upper voltage threshold, expanding the charge prohibition region.

The method, wherein the modifying may comprise, based on the detected voltage of the battery falling below the preset lower voltage threshold, expanding the discharge prohibition region.

According to the present disclosure, a vehicle may comprise, a battery of the vehicle, at least one sensor configured to detect at least one of a voltage, a current, or a temperature of the battery, a processor, and a memory storing at least one instruction that, when executed by the processor communicating with the memory, is configured to cause the vehicle to, determine, based on data from the at least one sensor, a state of health (SOH) of the battery, expand, based on the determined SOH, at least one of a charge prohibition region associated with state of charge (SOC) control of the battery or a discharge prohibition region associated with SOC control of the battery, and control, based on the expanded charge prohibition region, charging of the battery or control, based on the expanded discharge prohibition region, discharging of the battery.

The vehicle, wherein the at least one instruction, when executed by the processor communicating with the memory, is configured to cause the vehicle to expand the charge prohibition region by lowering a charge prohibition threshold, such that charging of the battery is suppressed at a lower SOC as the SOH decreases.

The vehicle, wherein the at least one instruction, when executed by the processor communicating with the memory, is configured to cause the vehicle to expand the discharge prohibition region by raising a discharge prohibition threshold, such that discharging of the battery is suppressed at a higher SOC as the SOH decreases.

The vehicle, wherein the at least one instruction, when executed by the processor communicating with the memory, is configured to cause the vehicle to, based on the voltage of the battery exceeding a preset upper voltage threshold or falling below a preset lower voltage threshold, expand the charge prohibition region or the discharge prohibition region.

### BRIEF DESCRIPTION OF THE DRAWINGS

The foregoing and other examples, features, and advantages, as well as the following detailed description of the examples, will be better understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIG. 1 shows an example of an apparatus for controlling a battery according to one example of the present disclosure.

FIG. 2 shows an example of a method for controlling a battery according to one example of the present disclosure.

FIG. 3A shows an example of an SOC control strategy in a state where a battery is not degraded, according to one example of the present disclosure.

FIG. 3B shows an example of a modification of an SOC control strategy based on a degradation state of a battery, according to one example of the present disclosure.

FIG. 4 shows an example of a reduction of a maximum power region of a maximum charge power map based on a degradation state of a battery, according to one example of the present disclosure.

FIG. 5 shows an example of a reduction of a maximum power region of a maximum discharge power map based on a degradation state of a battery, according to one example of the present disclosure.

FIG. 6 shows an example of how a charge prohibition region, a discharge prohibition region, a maximum power region of a maximum charge power map, and a maximum power region of a maximum discharge power map are changed based on a degradation state of a battery, according to one example of the present disclosure.

FIG. 7 is an example computing system.

### DETAILED DESCRIPTION

Hereinafter, examples disclosed in the present document will be described in detail with reference to the accompanying drawings. Like reference numerals designate like elements, and redundant descriptions thereof will be omitted. Further, such as “module” and a “unit”, suffixes for components used in the following description are given or mixed and used by considering easiness in preparing a specification and do not have a meaning or role distinguished from each other in themselves. In addition, in describing an example disclosed in the present document, if it is determined that a detailed description of a related art incorporated herein unnecessarily obscure the gist of the example, the detailed description thereof will be omitted. Furthermore, it should be understood that the appended drawings are intended only to help understand examples disclosed in the present document and do not limit the technical principles and scope of the present disclosure; rather, it should be understood that the appended drawings include all of the modifications, equivalents or substitutes described by the technical principles and belonging to the technical scope of the present disclosure.

Although the terms first, second, and the like, may be used herein to describe various elements, these elements should not be limited by these terms. These terms are generally only used to distinguish one element from another.

When an element or layer is referred to as being “on,” “engaged to,” “connected to,” or “coupled to” another element or layer, it may be directly on, engaged, connected, or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present.

When a component, unit, device, element, apparatus, or the like of the present disclosure is described as having a purpose or performing an operation, function, or the like, the component, unit, device, element, apparatus, or the like should be considered herein as being “configured to” meet that purpose or to perform that operation or function. Each component, unit, device, element, apparatus, and the like may separately embody or be included with a processor and a memory, such as a non-transitory computer readable media, as part of the apparatus.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, and C”, “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B.

The term “module” or “unit” used in the specification means a software and/or hardware component, and the “module” or “unit” performs certain operations/functions/roles. However, the “module” or “unit” is not construed as being limited to software or hardware. The “module” or “unit” may be configured to be in an addressable storage medium or to execute one or more processors. Therefore, as an example, the “module” or “unit” may include at least one of components such as software components, object-oriented software components, class components, and task components, processes, functions, attributes, procedures, sub-routines, segments of program codes, drivers, firmware, micro-codes, circuits, data, databases, data structures, tables, arrays, or variables. Functions provided in the components, “modules”, or “units” may be combined into a smaller number of components, “modules”, or “units” or further divided into additional components, “modules”, or “units”.

In the present disclosure, the “module” or “unit” may be realized as a processor and a memory. The “processor” should be widely construed to include a general-purpose processor, a central processing unit (CPU), a microprocessor, a digital signal processor (DSP), a microcontroller, a state machine, or the like. In some environments, the “processor” may refer to an application-specific integrated circuit (ASIC), a programmable logic device (PLD), or a field-programmable gate array (FPGA), and the like. For example, the “processor” may refer to a combination of processing devices such as a combination of a DSP and a microprocessor, a combination of a plurality of microprocessors, a combination of one or more microprocessors combined with a DSP core, or any other such combination. Moreover, the “memory” should be widely construed to include any electronic component capable of storing electronic information. The “memory” may refer to various types of processor-readable medium such as a random access memory (RAM), a read only memory (ROM), a non-volatile random access memory (NVRAM), a programmable read only memory (PROM), an erasable programmable read only memory (EPROM), an electrically erasable programmable read only memory (EEPROM), a flash memory, a magnetic or optical data storage device, and registers. When the processor can read information from a memory and/or record the information in the memory, the memory may be in a state of electronic communication with a processor. Memory integrated into a processor is in a state of electronic communication with the processor.

The one or more features described herein may be provided as a computer program stored in a computer-readable recording medium in order to be executed on a computer. The medium may either continuously store a computer-executable program or temporarily store the program for execution or download. Furthermore, the medium may be a variety of recording or storage means in the form of a single hardware device or multiple combined hardware devices, and is not limited to media directly connected to some computer system but may also be distributed across a network. Examples of such media include magnetic media such as a hard disk, a floppy disk, or a magnetic tape, optical recording media such as a CD-ROM or a DVD, magneto-optical media such as a floptical disk, and a ROM, RAM, or flash memory, among others, configured to store program instructions. Additional examples of such media include media or storage media that are managed by an app store that distributes applications or by various other sites or servers that provide or distribute software.

In a hardware implementation, processing units used for performing the techniques may be implemented within one or more ASICs, DSPs, digital signal processing devices, programmable logic devices, field-programmable gate arrays, processors, controllers, microcontrollers, microprocessors, electronic devices, or computers or combinations thereof designed to perform the functions described in the present disclosure.

An automation level of an autonomous driving vehicle may be classified as follows, according to the American Society of Automotive Engineers (SAE). At autonomous driving level 0, the SAE classification standard may correspond to “no automation,” in which an autonomous driving system is temporarily involved in emergency situations (e.g., automatic emergency braking) and/or provides warnings only (e.g., blind spot warning, lane departure warning, etc.), and a driver is expected to operate the vehicle. At autonomous driving level 1, the SAE classification standard may correspond to “driver assistance,” in which the system performs some driving functions (e.g., steering, acceleration, brake, lane centering, adaptive cruise control, etc.) while the driver operates the vehicle in a normal operation section, and the driver is expected to determine an operation state and/or timing of the system, perform other driving functions, and cope with (e.g., resolve) emergency situations. At autonomous driving level 2, the SAE classification standard may correspond to “partial automation,” in which the system performs steering, acceleration, and/or braking under the supervision of the driver, and the driver is expected to determine an operation state and/or timing of the system, perform other driving functions, and cope with (e.g., resolve) emergency situations. At autonomous driving level 3, the SAE classification standard may correspond to “conditional automation,” in which the system drives the vehicle (e.g., performs driving functions such as steering, acceleration, and/or braking) under limited conditions but transfer driving control to the driver when the required conditions are not met, and the driver is expected to determine an operation state and/or timing of the system, and take over control in emergency situations but do not otherwise operate the vehicle (e.g., steer, accelerate, and/or brake). At autonomous driving level 4, the SAE classification standard may correspond to “high automation,” in which the system performs all driving functions, and the driver is expected to take control of the vehicle only in emergency situations. At autonomous driving level 5, the SAE classification standard may correspond to “full automation,” in which the system performs full driving functions without any aid from the driver including in emergency situations, and the driver is not expected to perform any driving functions other than determining the operating state of the system. Although the present disclosure may apply the SAE classification standard for autonomous driving classification, other classification methods and/or algorithms may be used in one or more configurations described herein.

One or more features associated with autonomous driving control may be activated based on configured autonomous driving control setting(s) (e.g., based on at least one of: an autonomous driving classification, a selection of an autonomous driving level for a vehicle, etc.). Based on one or more features (e.g., feature of controlling discharging/charging of a battery of a vehicle) described herein, an operation of the vehicle may be controlled. The vehicle control may include various operational controls associated with the vehicle (e.g., autonomous driving control, sensor control, braking control, braking time control, acceleration control, acceleration change rate control, alarm timing control, forward collision warning time control, etc.). One or more auxiliary devices (e.g., engine brake, exhaust brake, hydraulic retarder, electric retarder, regenerative brake, etc.) may also be controlled, for example, based on one or more features (e.g., feature of controlling discharging/charging of a battery of a vehicle) described herein.

One or more communication devices (e.g., a modem, a network adapter, a radio transceiver, an antenna, etc., that is capable of communicating via one or more wired or wireless communication protocols, such as Ethernet, Wi-Fi, near-field communication (NFC), Bluetooth, Long-Term Evolution (LTE), 5G New Radio (NR), vehicle-to-everything (V2X), etc.) may also be controlled, for example, based on one or more features (e.g., feature of controlling discharging/charging of a battery of a vehicle) described herein.

Minimum risk maneuver (MRM) operation(s) may also be controlled, for example, based on one or more features (e.g., feature of controlling discharging/charging of a battery of a vehicle) described herein. A minimal risk maneuvering operation (e.g., a minimal risk maneuver, a minimum risk maneuver) may be a maneuvering operation of a vehicle to minimize (e.g., reduce) a risk of collision with surrounding vehicles in order to reach a lowered (e.g., minimum) risk state. A minimal risk maneuver may be an operation that may be activated during autonomous driving of the vehicle when a driver is unable to respond to a request to intervene. During the minimal risk maneuver, one or more processors of the vehicle may control a driving operation of the vehicle for a set period of time.

Biased driving operation(s) may also be controlled, for example, based on one or more features (e.g., feature of controlling discharging/charging of a battery of a vehicle) described herein. A driving control apparatus may perform a biased driving control. To perform a biased driving, the driving control apparatus may control the vehicle to drive in a lane by maintaining a lateral distance between the position of the center of the vehicle and the center of the lane. For example, the driving control apparatus may control the vehicle to stay in the lane but not in the center of the lane. The driving control apparatus may identify or determine a biased target lateral distance for biased driving control. For example, a biased target lateral distance may comprise an intentionally adjusted lateral distance that a vehicle may aim to maintain from a reference point, such as the center of a lane or another vehicle, during maneuvers such as lane changes. This adjustment may be made to improve the vehicle's stability, safety, and/or performance under varying driving conditions, etc. For example, during a lane change, the driving control system may bias the lateral distance to keep a safer gap from adjacent vehicles, considering factors such as the vehicle's speed, road conditions, and/or the presence of obstacles, etc.

One or more sensors (e.g., IMU sensors, camera, LIDAR, RADAR, blind spot monitoring sensor, line departure warning sensor, parking sensor, light sensor, rain sensor, traction control sensor, anti-lock braking system sensor, tire pressure monitoring sensor, seatbelt sensor, airbag sensor, fuel sensor, emission sensor, throttle position sensor, inverter, converter, motor controller, power distribution unit, high-voltage wiring and connectors, auxiliary power modules, charging interface, etc.) may also be controlled, for example, based on one or more features (e.g., feature of controlling discharging/charging of a battery of a vehicle) described herein. An operation control for autonomous driving of the vehicle may include various driving control of the vehicle by the vehicle control device (e.g., acceleration, deceleration, steering control, gear shifting control, braking system control, traction control, stability control, cruise control, lane keeping assist control, collision avoidance system control, emergency brake assistance control, traffic sign recognition control, adaptive headlight control, etc.).

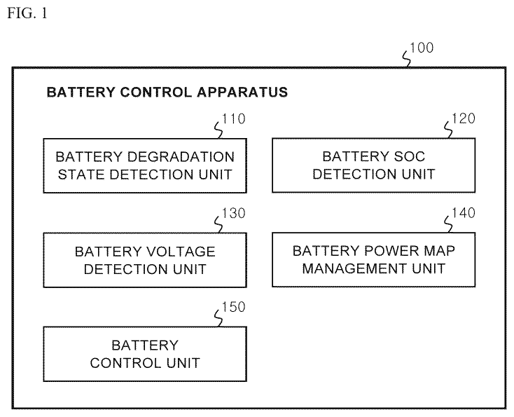

Hereinafter, an apparatus and method for controlling a battery according examples of the present disclosure will be described with reference to FIGS. 1 to 6 in detail.

According to the present disclosure, a battery of an electric vehicle may suffer battery degradation over time, which may affect safety and performance of the electric vehicle. As a battery ages, its capacity and ability to safely accept or deliver energy diminishes, increasing the risk of overcharging or over-discharging, which may harm the battery or even shut down the electric vehicle. The proposed method and apparatus address this by continuously assessing the battery's state of health (SOH) using real-time sensor data (e.g., voltage, current, or temperature, etc.) and then dynamically adjusting the boundaries (called “prohibition regions”) within which charging or discharging is allowed. When the battery's SOH falls below certain thresholds, the method expands these prohibition regions: it limits charging at higher states of charge and restricts discharging at lower states of charge. This approach helps prevent dangerous voltage conditions and extends the useful life of the battery, ensuring that even as the battery degrades, the electric vehicle operates safely and efficiently.

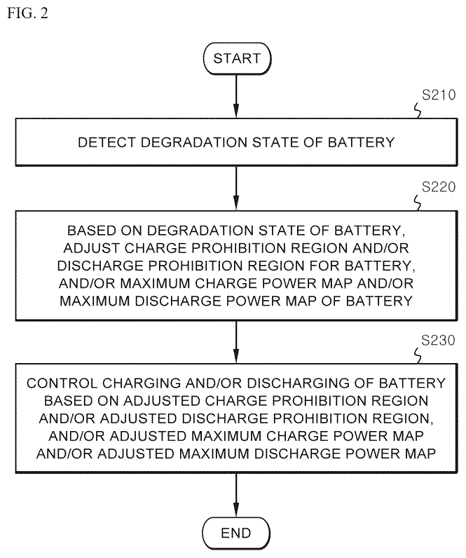

FIG. 1 shows an example of an apparatus for controlling a battery according to one example of the present disclosure, and FIG. 2 shows an example of a method for controlling a battery according to one example of the present disclosure.

Referring to FIG. 1, a battery control apparatus 100 according to one example of the present disclosure may include a battery degradation state detection unit 110, a battery state of charge (SOC) detection unit 120, a battery voltage detection unit 130, a battery power map management unit 140, a battery control unit 150, a temperature sensor, a current sensor, a voltage sensor, and the like (e.g., CAN communication modules, relay drivers, or DC-DC converters, etc.).

The battery degradation state detection unit 110 may be configured to detect a degradation state of the battery by using an existing state of health (SOH) estimation method, such as a direct measurement method, a model-based estimation method, a data-driven estimation method, or an adaptive filter method (e.g., Kalman filter, neural network, or equivalent circuit model, etc.) (see S210 of FIG. 2).

The battery SOC detection unit 120 may be configured to detect a state of charge of the battery by using an existing SOC estimation method, such as a voltage measurement method, an open circuit voltage (OCV) measurement method, a current integration method, a chemical measurement method, or a pressure measurement method (e.g., coulomb counting, internal resistance estimation, or gas pressure-based sensing, etc.).

The battery voltage detection unit 130 may be configured to detect a voltage of the battery by using an existing voltage measurement method, such as an OCV measurement method (e.g., steady-state voltage sampling, lookup table correlation, or curve fitting techniques, etc.).

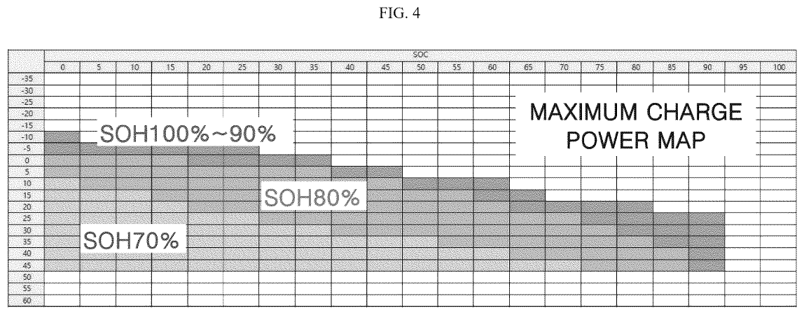

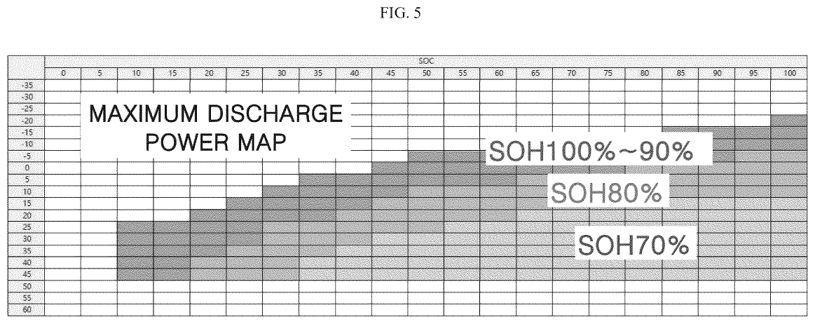

The battery power map management unit 140 may be configured to manage (e.g., retrieve, modify, update, store, delete, etc.) a maximum charge power map and/or a maximum discharge power map of the battery. For reference, the maximum charge power map of the battery may be a map indicating a maximum charge power value of the battery corresponding to the temperature and SOC of the battery (e.g., high charge power at low SOC and moderate temperature, or low charge power at high SOC or low temperature, etc.) (see FIG. 4), and the maximum discharge power map of the battery may be a map indicating a maximum discharge power value of the battery corresponding to the temperature and SOC of the battery (e.g., limited discharge at cold temperatures or near-empty SOC, etc.) (see FIG. 5).

The battery control unit 150 may be configured to cooperate with the battery degradation state detection unit 110, the battery SOC detection unit 120, the battery voltage detection unit 130, and the battery power map management unit 140, and may be configured to control charging and/or discharging of the battery by modifying an SOC control strategy (scheme) based on a degradation state and operating conditions of the battery (e.g., ambient temperature, driving pattern, or regenerative braking intensity, etc.).

For example, the battery control unit 150 may be configured to adjust a charge prohibition region (critical high SOC region) and/or a discharge prohibition region (critical low SOC region), which are defined based on the SOC of the battery, based on the degradation state of the battery detected by the battery degradation state detection unit 110 (see S220 of FIG. 2), and may be configured to control charging and/or discharging of the battery based on the SOC control strategy reflecting the adjusted charge prohibition region and/or discharge prohibition region (e.g., extending the no-charge region when SOH is 70%, or narrowing the usable SOC band in cold weather, etc.) (see S230 of FIG. 2).

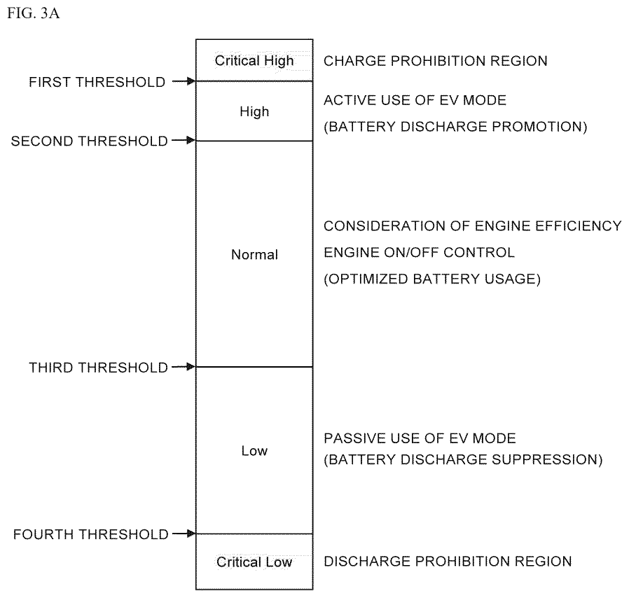

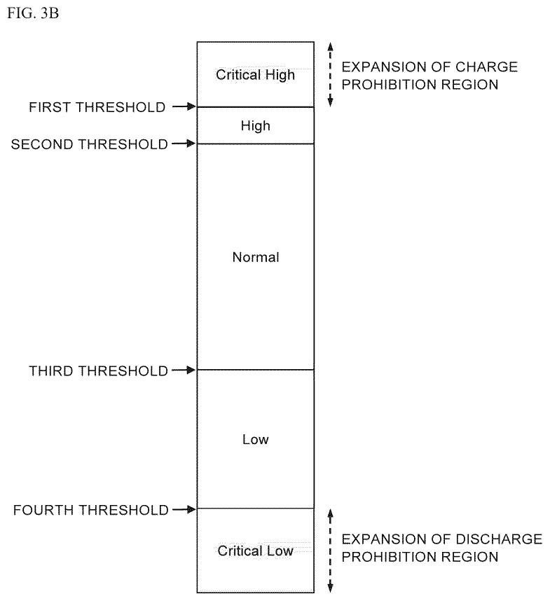

In this regard, FIG. 3A shows an example of an SOC control strategy (scheme) in a state where a battery is not degraded, and FIG. 3B shows an example of a modification of an SOC control strategy based on a degradation state of a battery, according to one example of the present disclosure (e.g., critical SOC boundaries are shifted inward as SOH declines from 100% to 70%, etc.).

Referring to FIGS. 3A and 3B, the battery control unit 150 may be configured to control charging and/or discharging of the battery based on the SOC control strategy. As illustrated in FIG. 3A, based on the battery being in a state of health (SOH) of 100%, indicating that there is little or no degradation, charging and/or discharging of the battery may be performed according to the SOC control strategy that may be set, for example, during vehicle development (e.g., enabling full utilization between 10% and 90% SOC under nominal load and temperature conditions, etc.).

Referring to FIG. 3A, for example, the SOC control strategy may be configured as follows:

A charge prohibition region (Critical High SOC region): an SOC region in which the SOC is equal to or greater than a first threshold and in which charging is prohibited (e.g., to prevent overvoltage during downhill regenerative braking, prolonged fast charging, or extended high-speed cruising, etc.).
A high SOC region: an SOC region in which the SOC is less than the first threshold and equal to or greater than a second threshold, and in which EV mode is actively used to promote battery discharging (e.g., during stop-and-go traffic, short-distance EV trips, or gradual highway merging, etc.).
A normal SOC region: an SOC region in which the SOC is less than the second threshold and equal to or greater than a third threshold, and in which engine on/off may be controlled based on engine efficiency to enhance or optimize battery usage (e.g., enabling hybrid blending during urban cruising, acceleration, or light-load hill climbing, etc.).
A low SOC region: an SOC region in which the SOC is less than the third threshold and equal to or greater than a fourth threshold, and in which EV mode is passively used to suppress battery discharging (e.g., by limiting EV use during parking maneuvers, engine warm-up, or low-speed deceleration, etc.).
A discharge prohibition region (Critical Low SOC region): an SOC region in which the SOC is less than the fourth threshold and in which discharging is prohibited (e.g., to prevent battery cutoff during steep uphill driving, prolonged idling with HVAC, or heavy acceleration, etc.).

However, as the degradation state of the battery becomes more severe, the battery control unit 150 may be configured to modify the SOC control strategy such that, as illustrated in FIG. 3B, the first threshold (i.e., the lower limit of the charge prohibition region) is lowered to expand the charge prohibition region, and/or the fourth threshold (i.e., the upper limit of the discharge prohibition region) is raised to expand the discharge prohibition region, thereby preventing overvoltage and/or undervoltage (e.g., due to reduced capacity or increased internal resistance at SOH below a threshold level, etc.).

The battery control unit 150 may be configured to control charging and/or discharging of the battery based on the SOC of the battery detected by the battery SOC detection unit 120, according to the modified SOC control strategy (e.g., updated SOC bands applied dynamically based on real-time SOH data, etc.).

According to one example of the present disclosure, the battery control unit 150 may be configured to, along with or separately from the expansion of the charge prohibition region and/or the discharge prohibition region based on the degradation state of the battery as described above, modify a maximum charge power map and/or a maximum discharge power map managed by the battery power map management unit 140 based on the degradation state of the battery (e.g., SOH decline due to repeated deep discharges, fast charging cycles, or thermal cycling, etc.) (see S220 of FIG. 2), and may be configured to control charging and/or discharging of the battery based on the modified maximum charge power map and/or maximum discharge power map (e.g., limiting maximum allowable regenerative braking current or acceleration power at a threshold SOH level, etc.) (see S230 of FIG. 2).

In this regard, FIG. 4 shows an example of a reduction of a maximum power region of a maximum charge power map based on a degradation state of a battery, and FIG. 5 shows an example of a reduction of a maximum power region of a maximum discharge power map based on a degradation state of a battery (e.g., from full utilization at a first SOH threshold level to de-rated usage at a second SOH threshold level that is less than the first SOH threshold level, etc.).

Referring to FIG. 4, a maximum charge power map of the battery may be a map indicating a maximum charge power value of the battery corresponding to the temperature and SOC of the battery (e.g., higher charge power at moderate temperatures and low SOC, or reduced charge power at high SOC or low temperatures, etc.). The battery power map management unit 140, which may operate in cooperation with the battery control unit 150, may be configured to modify the maximum charge power map such that, as the degradation of the battery becomes more severe (e.g., as the SOH decreases from 100% to 90%, 80%, and 70% due to cycle aging, calendar aging, or thermal stress, etc.), a maximum power region is reduced. The battery control unit 150 may be configured to control charging of the battery based on the modified maximum charge power map (e.g., reducing charging current limits during fast charging events, etc.).

Likewise, referring to FIG. 5, a maximum discharge power map of the battery may be a map indicating a maximum discharge power value of the battery corresponding to the temperature and SOC of the battery (e.g., reduced discharge limits at low temperatures, high SOC, or low SOH, etc.). The battery power map management unit 140, which may operate in cooperation with the battery control unit 150, may be configured to modify the maximum discharge power map such that, as the degradation of the battery becomes more severe (e.g., as the SOH decreases from 100% to 90%, 80%, and 70% due to cycle aging, thermal stress, or high-load usage, etc.), a maximum power region is reduced. The battery control unit 150 may be configured to control discharging of the battery based on the modified maximum discharge power map (e.g., restricting torque output from the electric motor to avoid voltage drop, etc.).

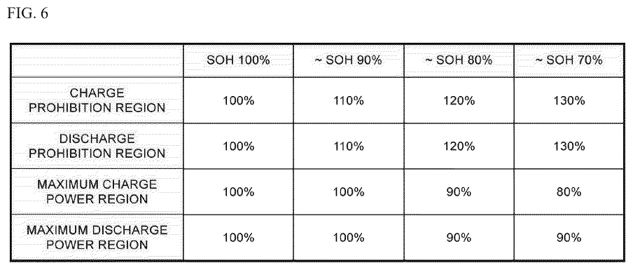

FIG. 6 shows an example of how a charge prohibition region, a discharge prohibition region, a maximum power region of a maximum charge power map, and a maximum power region of a maximum discharge power map are changed based on a degradation state of a battery, according to one example of the present disclosure (e.g., showing progressive reduction of power and usable SOC range across SOH levels from 100% to 70%, etc.).

The degradation state of the battery generally becomes more severe in proportion to the passage of time, battery usage duration, vehicle mileage, and similar factors (e.g., repeated fast charging, prolonged high-temperature exposure, or frequent deep cycling, etc.). As illustrated in FIG. 6, according to one example of the present disclosure, the charge prohibition region and the discharge prohibition region may be expanded based on the degradation state of the battery. Specifically, as the SOH decreases from 100% to 90%, 80%, and 70%, the prohibition regions may be proportionally expanded from an initial size of 100% to 110%, 120%, and 130%, respectively (e.g., by shifting the critical SOC limits inward to reduce usable SOC range, etc.).

Meanwhile, the maximum power region of the maximum charge power map and the maximum power region of the maximum discharge power map may be gradually reduced beginning at a predetermined SOH threshold (e.g., SOH 80%), at which charge and discharge capabilities decline markedly (e.g., due to rising internal resistance or reduced capacity, etc.). For example, based on the SOH of the battery being equal to or less than 100% and greater than a predetermined threshold value (e.g., SOH 80%), the battery power map management unit may be configured to retain the maximum power region of the maximum charge power map and the maximum power region of the maximum discharge power map, which are set for a state where the SOH of the battery is (or assumed to be) at 100%. If the SOH of the battery is equal to or less than the predetermined threshold value (e.g., SOH 80%), the battery power map management unit may be configured to reduce the maximum power region of the maximum charge power map and the maximum power region of the maximum discharge power map based on a decrease in the SOH of the battery (e.g., reducing allowable peak current during regenerative braking or acceleration, etc.).

Accordingly, one example of the present disclosure may enable efficient control of charging and/or discharging of the battery so as to prevent overvoltage and/or undervoltage of the battery, by expanding the charge prohibition region and/or the discharge prohibition region and, together with or separately from this, reducing the maximum power region of the maximum charge power map and/or the maximum discharge power map, based on the degradation state of the battery (e.g., SOH drop due to calendar aging, repeated fast charging, or extended high-load operation, etc.).

According to one example of the present disclosure, the battery control unit 150 may be configured to control charging and/or discharging of the battery such that, for example, based on the voltage of the battery detected by the battery voltage detection unit 130 during vehicle driving when the voltage reaches an abnormal voltage range (e.g., a high-voltage range exceeding 4.2V due to aggressive regenerative braking, or a low-voltage range below 2.5V during steep uphill driving in EV mode, etc.), a charge prohibition region and/or a discharge prohibition region of an SOC control strategy is expanded, allowing the battery voltage to exit the high-voltage and/or low-voltage range. The battery control unit 150 may be configured to expand the charge prohibition region of the SOC control strategy based on the voltage of the battery reaching a predetermined high-voltage range (e.g., a high-voltage range exceeding 4.2V), and to expand the discharge prohibition region of the SOC control strategy based on the voltage of the battery reaching a predetermined low-voltage range (e.g., a low-voltage range below 2.5V during rapid acceleration or cold-weather discharge, etc.), thereby controlling charging and/or discharging of the battery such that the battery voltage exits the high-voltage and/or low-voltage range.

Thereafter, the battery control unit 150 may be configured to reset the charge prohibition region and/or the discharge prohibition region of the SOC control strategy based on the degradation state of the battery detected by the battery degradation state detection unit 110, thereby stably and adaptively controlling charging and/or discharging of the battery (e.g., by reapplying SOH-based SOC limits after voltage normalization, periodic recalibration, or ignition cycle reset, etc.).

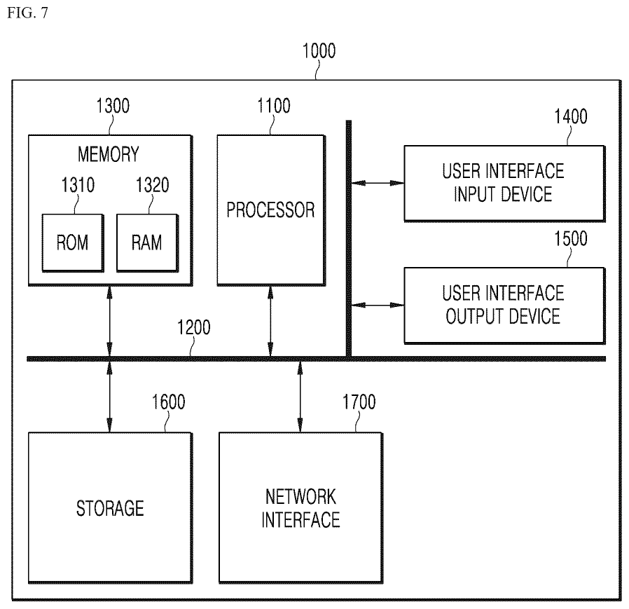

FIG. 7 shows an example computing system (e.g., a computing device of a battery control apparatus or any other apparatus). One or more controllers, processors, etc. described herein, such as one or more components of a battery control apparatus, one or more components of a vehicle, and any other components and devices disclosed herein, may be implemented by or in the computing system as shown in FIG. 7.

A computing system 1000 may include at least one processor 1100, memory 1300, a user interface input device 1400, a user interface output device 1500, a storage 1600, and a network interface 1700, which are connected with each other via a bus 1200.

The processor 1100 may be a central processing unit (CPU) or a semiconductor device that processes instructions stored in the memory 1300 and/or the storage 1600. Each of the memory 1300 and the storage 1600 may include various types of volatile or nonvolatile storage media. For example, the memory 1300 may include a read-only memory (ROM) and a random-access memory (RAM).

Communication interface(s) (also referred to as communication device(s), communicator(s), communication module(s), communication unit(s), etc.), such as the network interface 1700, may allow software and/or data to be transferred between a device and one or more external devices, and/or between one or more components of a device. Communication interface(s) may include a receiver, a transmitter, a transceiver, a modem, a network interface and/or adapter (such as an Ethernet adapter), a radio transceiver, an antenna, a communication port, a Personal Computer Memory Card International Association (PCMCIA) slot and card, or the like. Software and data transferred via communication interface(s) may be in the form of signals, which may be electronic, electromagnetic, optical, infrared, or other signals capable of being received by communication interface(s). These signals may be provided to communication interface(s) via a communication path of a device, which may be implemented using, for example, wire or cable, fiber optics, a cellular link, a radio frequency (RF) link and/or other communications channels. Communication interface(s) may communicate using one or more communication protocols, such as Ethernet, Wi-Fi, near-field communication (NFC), Infrared Data Association (IrDA), Bluetooth, Bluetooth low energy (BLE), Zigbee, Long-Term Evolution (LTE), 5G New Radio (NR), vehicle-to-everything (V2X), a controller area network (CAN), or a local interconnect network (LIN), etc.

Accordingly, the operations of the method or algorithm described in connection with example example(s) disclosed in the specification may be directly implemented with a hardware module, a software module, or a combination of the hardware module and the software module, which is executed by the processor 1100. The software module may reside on a storage medium (e.g., the memory 1300 and/or the storage 1600) such as RAM, a flash memory, ROM, an erasable and programmable ROM (EPROM), an electrically EPROM (EEPROM), a register, a hard disk drive, a removable disc, or a compact disc-ROM (CD-ROM).

The storage medium may be coupled to the processor 1100. The processor 1100 may read out information from the storage medium and may write information in the storage medium. Alternatively, the storage medium may be integrated with the processor 1100. The processor and storage medium may be implemented with an application specific integrated circuit (ASIC). The ASIC may be provided in a user terminal. Alternatively, the processor and storage medium may be implemented with separate components in the user terminal.

The present disclosure is directed to providing an apparatus and method for controlling a battery, which modify SOC control strategies based on a degradation state of the battery.

In addition, the present disclosure is directed to providing an apparatus and method for controlling a battery, which control charging and/or discharging of the battery by adjusting a charge prohibition region and/or a discharge prohibition region of an SOC control strategy based on a degradation state of the battery.

Further, the present disclosure is directed to providing an apparatus and method for controlling a battery, which control charging and/or discharging of the battery by adjusting a maximum charge power map and/or a maximum discharge power map of the battery based on a degradation state of the battery.

Examples of the present disclosure is not limited to those mentioned above, and other examples and advantages not mentioned above will be understood from the following description, and become more apparent from the examples. Moreover, examples of the present disclosure may be realized by the means and combinations thereof indicated in claims.

An example of the present disclosure may provide an apparatus for controlling a battery, the apparatus including a battery degradation state detection unit configured to detect a degradation state of the battery based on a state of health (SOH) of the battery, and a battery control unit configured to control at least one of charging or discharging of the battery by expanding, based on the degradation state of the battery, at least one of a charge prohibition region or a discharge prohibition region of a state of charge (SOC) control strategy of the battery.

The battery control unit may be configured to, based on the degradation state of the battery, lower a lower limit of the charge prohibition region and raise an upper limit of the discharge prohibition region, the charge prohibition region and the discharge prohibition region being defined based on the SOC of the battery.

The SOC control strategy may include a high SOC region, a normal SOC region, and a low SOC region between the lower limit of the charge prohibition region and the upper limit of the discharge prohibition region, and the battery control unit may be configured to control charging and discharging of the battery such that the discharging is promoted in the high SOC region and suppressed in the low SOC region.

The apparatus for controlling the battery may further include a battery power map management unit configured to manage at least one of a maximum charge power map or a maximum discharge power map of the battery, and the battery power map management unit may be configured to reduce at least one of a maximum power region of the maximum charge power map or a maximum power region of the maximum discharge power map based on the degradation state of the battery.

The battery power map management unit may be configured to maintain the maximum power region of the maximum charge power map and the maximum power region of the maximum discharge power map, which are set for a state where the SOH of the battery is 100%, based on the SOH of the battery exceeding a predetermined threshold value that is equal to or less than 100%, and reduce the maximum power region of the maximum charge power map and the maximum power region of the maximum discharge power map, each in response to a decrease in the SOH of the battery, based on the SOH of the battery being equal to or less than the predetermined threshold value.

The apparatus for controlling the battery may further include a battery voltage detection unit configured to detect a voltage of the battery, and the battery control unit may be configured to control at least one of charging or discharging of the battery by expanding at least one of the charge prohibition region or the discharge prohibition region based on the voltage of the battery reaching an abnormal voltage region.

The battery control unit may be configured to expand the charge prohibition region based on the voltage of the battery reaching a predetermined high-voltage region, thereby controlling charging and discharging of the battery.

The battery control unit may be configured to expand the discharge prohibition region based on the voltage of the battery reaching a predetermined low-voltage region, thereby controlling charging and discharging of the battery.

Another example of the present disclosure may provide a method for controlling a battery, the method including detecting a degradation state of the battery based on a state of health (SOH) of the battery, modifying a state of charge (SOC) control strategy by expanding, based on the degradation state of the battery, at least one of a charge prohibition region or a discharge prohibition region of the SOC control strategy, and controlling at least one of charging or discharging of the battery based on the modified SOC control strategy.

The modifying may include lowering a lower limit of the charge prohibition region based on the degradation state of the battery and raising an upper limit of the discharge prohibition region based on the degradation state of the battery, the charge prohibition region and the discharge prohibition region being defined based on the SOC of the battery.

The SOC control strategy may include a high SOC region, a normal SOC region, and a low SOC region between the lower limit of the charge prohibition region and the upper limit of the discharge prohibition region, and the controlling may include controlling charging and discharging of the battery such that the discharging is promoted in the high SOC region and suppressed in the low SOC region.

The method for controlling the battery may further include, prior to the controlling, reducing at least one of a maximum power region of a maximum charge power map of the battery or a maximum power region of a maximum discharge power map of the battery based on the degradation state of the battery, and the controlling may include controlling at least one of charging or discharging of the battery based on the maximum charge power map and the maximum discharge power map.

The reducing may include maintaining the maximum power region of the maximum charge power map and the maximum power region of the maximum discharge power map, which are set for a state where the SOH of the battery is 100%, based on the SOH of the battery exceeding a predetermined threshold value, and reducing the maximum power region of the maximum charge power map and the maximum power region of the maximum discharge power map, each in response to a decrease in the SOH of the battery, based on the SOH of the battery being equal to or less than the predetermined threshold value.

The method for controlling the battery may further include, prior to the modifying, detecting a voltage of the battery, and the modifying may include expanding at least one of the charge prohibition region or the discharge prohibition region of the SOC control strategy based on the voltage of the battery reaching an abnormal voltage range.

The expanding may include expanding the charge prohibition region based on the voltage of the battery reaching a predetermined high-voltage region.

The expanding may include expanding the discharge prohibition region based on the voltage of the battery reaching a predetermined low-voltage region.

According to examples of the present disclosure, as the degradation state of the battery becomes more severe, the charge prohibition region and/or the discharge prohibition region of the SOC control strategy is expanded to a greater extent to control charging and/or discharging of the battery, thereby preventing a rapid voltage rise at a high SOC and a rapid voltage drop at a low SOC, and improving durability and safety of the battery.

In addition, according to examples of the present disclosure, as the degradation state of the battery becomes more severe, charging of the battery is controlled by reducing a maximum power region of a maximum charge power map of the battery, or discharging of the battery is controlled by reducing a maximum power region of a maximum discharge power map of the battery, thereby preventing a rapid voltage rise at a high SOC and a rapid voltage drop at a low SOC, and improving durability and safety of the battery.

As used in the present disclosure (especially in the appended claims), the terms “a/an” and “the” include both singular and plural references, unless the context clearly states otherwise. Also, it should be understood that any numerical range recited in the present disclosure is intended to include all sub-ranges subsumed therein (unless expressly indicated otherwise) and accordingly, the disclosed numeral ranges include every individual value between the minimum and maximum values of the numeral ranges.

The steps constituting the method according to the present disclosure may be performed in an appropriate order unless a specific order is described or otherwise specified. That is, the present disclosure is not necessarily limited to the order in which the steps are recited. All examples described in the present disclosure or the terms indicative thereof (“for example”, “such as”) are merely to describe the present disclosure in greater detail. Therefore, it should be understood that the scope of the present disclosure is not limited to the example examples described above or by the use of such terms unless limited by the appended claims. Also, it should be apparent to those skilled in the art that various modifications, combinations, and alternations may be made depending on design conditions and factors within the scope of the appended claims or equivalents thereof.

The present disclosure is thus not limited to the example examples described above, and rather intended to include the following appended claims, and all modifications, equivalents, and alternatives falling within the spirit and scope of the following claims.

What is claimed is:

1. An apparatus for a vehicle, the apparatus comprising:
a processor; and
a memory storing at least one instruction that, when executed by the processor communicating with the memory, is configured to cause the apparatus to:
determine, via at least one sensor of the vehicle and based on a state of health (SOH) of a battery of the vehicle, a degradation state of the battery,
output a signal indicating the determined degradation state of the battery, and
control, based on the signal, at least one of charging or discharging of the battery by expanding at least one of a charge prohibition region or a discharge prohibition region of a state of charge (SOC) control strategy of the battery.

2. The apparatus of claim 1, wherein the at least one instruction, when executed by the processor communicating with the memory, is configured to cause the apparatus to, based on the determined degradation state of the battery, lower a lower limit of the charge prohibition region and raise an upper limit of the discharge prohibition region, and wherein the charge prohibition region and the discharge prohibition region are defined based on an SOC of the battery.

3. The apparatus of claim 2, wherein the SOC control strategy defines:
a first SOC region between the lower limit of the charge prohibition region and a first threshold SOC value of the battery,
a second SOC region between the first threshold SOC value and a second threshold SOC value of the battery, and
a third SOC region between the second threshold SOC value and the upper limit of the discharge prohibition region, and
wherein the at least one instruction, when executed by the processor communicating with the memory, is configured to cause the apparatus to control charging and discharging of the battery such that the discharging is promoted in the first SOC region and suppressed in the third SOC region.

4. The apparatus of claim 1, wherein the at least one instruction, when executed by the processor communicating with the memory, is configured to cause the apparatus to:
retrieve at least one of a maximum charge power map or a maximum discharge power map of the battery, and
reduce, based on the determined degradation state of the battery, at least one of a maximum power region of the maximum charge power map or a maximum power region of the maximum discharge power map.

5. The apparatus of claim 4, wherein the at least one instruction, when executed by the processor communicating with the memory, is configured to cause the apparatus to:
based on the SOH of the battery exceeding a predetermined threshold value, retain the maximum power region of the maximum charge power map and the maximum power region of the maximum discharge power map; and
based on the SOH of the battery being equal to or less than the predetermined threshold value, reduce the maximum power region of the maximum charge power map and the maximum power region of the maximum discharge power map.

6. The apparatus of claim 1, wherein the at least one instruction, when executed by the processor communicating with the memory, is configured to cause the apparatus to:
detect, via a voltage sensor of the vehicle, a voltage of the battery, and
based on the detected voltage of the battery exceeding a preset upper voltage threshold or falling below a preset lower voltage threshold, control at least one of charging or discharging of the battery by expanding at least one of the charge prohibition region or the discharge prohibition region.

7. The apparatus of claim 6, wherein the at least one instruction, when executed by the processor communicating with the memory, is configured to cause the apparatus to, based on the detected voltage of the battery exceeding the preset upper voltage threshold and expanding the charge prohibition region, restrict charging of the battery.

8. The apparatus of claim 6, wherein the at least one instruction, when executed by the processor communicating with the memory, is configured to cause the apparatus to, based on the detected voltage of the battery falling below the preset lower voltage threshold and expanding the discharge prohibition region, restrict discharging of the battery.

9. A method performed by an apparatus, the method comprising:
determining, via at least one sensor and based on a state of health (SOH) of a battery, a degradation state of the battery;
outputting a signal indicating the determined degradation state of the battery; modifying, based on the signal, a state of charge (SOC) control strategy by expanding at least one of a charge prohibition region or a discharge prohibition region of the SOC control strategy; and
controlling, based on the modified SOC control strategy, at least one of charging or discharging of the battery.

10. The method of claim 9, wherein the modifying comprises, based on the determined degradation state of the battery:
lowering a lower limit of the charge prohibition region; and
raising an upper limit of the discharge prohibition region, and wherein the charge prohibition region and the discharge prohibition region are defined based on an SOC of the battery.

11. The method of claim 10, wherein the SOC control strategy defines:
a first SOC region between the lower limit of the charge prohibition region and a first threshold SOC value of the battery,
a second SOC region between the first threshold SOC value and a second threshold SOC value of the battery, and
a third SOC region between the second threshold SOC value and the upper limit of the discharge prohibition region, and
wherein the controlling comprises controlling charging and discharging of the battery such that the discharging is promoted in the first SOC region and suppressed in the third SOC region.

12. The method of claim 9, further comprising, prior to the controlling, reducing, based on the determined degradation state of the battery, at least one of a maximum power region of a maximum charge power map of the battery or a maximum power region of a maximum discharge power map of the battery, wherein the controlling comprises controlling, based on the maximum charge power map and the maximum discharge power map, at least one of charging or discharging of the battery.

13. The method of claim 12, wherein the reducing comprises:
based on the SOH of the battery exceeding a predetermined threshold value, retaining the maximum power region of the maximum charge power map and the maximum power region of the maximum discharge power map; and
based on the SOH of the battery being equal to or less than the predetermined threshold value, reducing the maximum power region of the maximum charge power map and the maximum power region of the maximum discharge power map.

14. The method of claim 9, further comprising, prior to the modifying, detecting, via a voltage sensor, a voltage of the battery,
wherein the modifying comprises, based on the detected voltage of the battery exceeding a preset upper voltage threshold or falling below a preset lower voltage threshold, expanding at least one of the charge prohibition region or the discharge prohibition region of the SOC control.

15. The method of claim 14, wherein the modifying comprises, based on the detected voltage of the battery exceeding the preset upper voltage threshold, expanding the charge prohibition region.

16. The method of claim 14, wherein the modifying comprises, based on the detected voltage of the battery falling below the preset lower voltage threshold, expanding the discharge prohibition region.

17. A vehicle comprising:
a battery of the vehicle;
at least one sensor configured to detect at least one of a voltage, a current, or a temperature of the battery;
a processor; and
a memory storing at least one instruction that, when executed by the processor communicating with the memory, is configured to cause the vehicle to:
determine, based on data from the at least one sensor, a state of health (SOH) of the battery,
expand, based on the determined SOH, at least one of a charge prohibition region associated with state of charge (SOC) control of the battery or a discharge prohibition region associated with SOC control of the battery, and
control, based on the expanded charge prohibition region, charging of the battery or control, based on the expanded discharge prohibition region, discharging of the battery.

18. The vehicle of claim 17, wherein the at least one instruction, when executed by the processor communicating with the memory, is configured to cause the vehicle to expand the charge prohibition region by lowering a charge prohibition threshold, such that charging of the battery is suppressed at a lower SOC as the SOH decreases.

19. The vehicle of claim 17, wherein the at least one instruction, when executed by the processor communicating with the memory, is configured to cause the vehicle to expand the discharge prohibition region by raising a discharge prohibition threshold, such that discharging of the battery is suppressed at a higher SOC as the SOH decreases.

20. The vehicle of claim 17, wherein the at least one instruction, when executed by the processor communicating with the memory, is configured to cause the vehicle to, based on the voltage of the battery exceeding a preset upper voltage threshold or falling below a preset lower voltage threshold, expand the charge prohibition region or the discharge prohibition region.
